(19) United States
(12) Patent Application Publication
(10) Pub. No.: US 2011/0209908 A1
(43) Pub. Date: Sep. 1, 2011

(54) CONDUCTOR PACKAGE STRUCTURE AND METHOD OF THE SAME

(75) Inventors: Diann-Fang Lin, Zhubei City (TW); Yu-Shan Hu, Yangmei Township (TW)

(73) Assignee: Advanced Chip Engineering Technology Inc.

(21) Appl. No.: 12/971,134

(22) Filed: Dec. 17, 2010

Related U.S. Application Data
(63) Continuation-in-part of application No. 12/536,546, filed on Aug. 6, 2009.

(51) Int. Cl. H05K 1/02; H05K 1/18

(52) U.S. Cl. 174/258; 174/260

(57) ABSTRACT

The present invention provides a conductor package structure comprising a redistribution layer. An adhesive layer is formed on the redistribution layer. An electronic element is formed on the adhesive layer. Conductors are forming signal connection between the surface of a filling material and the bottom of the filling material, wherein the filling material is filled in the space between the electronic element and the conductors.

### RELATED APPLICATIONS

The present application is a Continuation-in-Part of U.S. application Ser. No. 12/536,546 filed Aug. 6, 2009 for “Conductor Package Structure and Method of the Same.”

### FIELD OF THE INVENTION

This invention relates to a structure of a package, and more particularly to a conductor package structure with signal channels.

### BACKGROUND OF THE INVENTION

### Description of the Prior Art

In the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As semiconductors become more complicated, the traditional package technique, for example lead frame package, flex package, rigid package technique, cannot meet the demand of producing a smaller chip with high density elements on the chip.

Typically, semiconductor devices require protection from moisture and mechanical damage. The structure involves the technology of a package. In the technology, the semiconductor dies or chips are usually individually packaged in a plastic or ceramic package. The package is required to protect the die and spread the heat generated by the devices. Therefore, heat dissipation is very important in semiconductor devices, particularly the power and the performance of the device increase.

Furthermore, conventional package technologies have to divide a dice on a wafer into respective dies and then package the die respectively. Therefore, these techniques are time consuming for the manufacturing process. The chip package technique is highly influenced by the development of integrated circuits. Therefore, as the size of the electronics has become more demanding, so does the package technique. For the reasons mentioned above, the trend of the package technique today is toward ball grid array (BGA), flip chip (FC-BGA), chip scale package (CSP), and wafer level package (WLP). “Wafer level package” is to be understood as meaning that the entire packaging and all the interconnections on the wafer as well as other processing steps are carried out before the singulation (dicing) into chips (dice). Generally, after completion of all assembling processes or packaging processes, individual semiconductor packages are separated from a wafer having a plurality of semiconductor dies. The wafer level package has extremely small dimensions combined with extremely good electrical properties.

WLP technique is an advanced packaging technology, by which the die are manufactured and tested on the wafer, and then singulated by dicing for assembly in a surface-mount line. The wafer level package technique utilizes the whole wafer as one object, not utilizing a single chip or die. Therefore, before performing a scribing process, packaging and testing has been accomplished. Furthermore, WLP is such an advanced technique so that the process of wire bonding, die mount and under-fill can be omitted. By utilizing WLP technique, the cost and manufacturing time can be reduced, and the resulting structure of WLP can be equal to the die. Therefore, this technique can meet the demands of miniaturization of electronic devices.

Although WLP technique has the advantages mentioned above, some issues still exist with respect to influencing the acceptance of WLP technique. For example, although utilizing WLP technique can reduce the CTE (coefficient of thermal expansion) mismatch the between IC (integrated circuit) and the interconnecting substrate, as the size of the device minimizes, the CTE difference between the materials of a structure of WLP becomes another critical factor to mechanical instability of the structure. Furthermore, in this wafer-level chip-scale package, a plurality of bond pads formed on the semiconductor die is redistributed through conventional redistribution processes involving a redistribution layer into a plurality of metal pads in an area array type. Solder balls are directly fused on the metal pads, which are formed in the area array type by means of the redistribution process. Typically, all of the stacked redistribution layers are formed over the built-up layer over the die. Therefore, the thickness of the package is increased. This may conflict with the demand of reducing the size of a chip.

Therefore, the present invention provides a conductor package structure to reduce the package thickness to overcome the aforementioned problem and also provide a better board level reliability test of temperature cycling.

### SUMMARY OF THE INVENTION

The present invention provides a conductor package structure comprises a redistribution layer. An adhesive layer is formed on the redistribution layer. At least one electronic element is formed on the adhesive layer. A plurality of conductors are forming signal connection between the surface of a filling material and the bottom of the filling material, wherein the filling material is filled in the space between the plurality of conductors and around the electric element.

The redistribution layer is formed between the conductors, and the bottom of the conductors and the bottom of the redistribution layer are coplanar. The redistribution layer further comprises at least one through opening formed therein The adhesive layer comprises conductive material. The filling material is adjacent to the side wall of the electronic element and the redistribution layer, and covering the active side of the electronic element. The conductor package structure further comprises a conductive layer formed between said electronic element and said adhesive layer. The conductor package structure further comprises a conductive material formed under the conductors and the redistribution layer. The conductor package structure further comprises signal channels formed over the electronic element and connecting between the electronic element and the connectors. The conductor package structure further comprises a dielectric layer formed under the signal channels. The conductor package structure further comprises a protective layer formed over the dielectric layer. The conductor package structure further comprises a marking layer formed over the protective layer. The bottom of the conductors has a concave shape portion formed therein.

It should be noted that the present invention provides a method for forming a conductor package structure. Firstly, the process includes providing a tooling with alignment mark formed thereon. Next, a laminate film is formed on the tooling. Subsequently, die pads of dice are aligned to the alignment mark. The dice are bonded onto the laminate film. Then, a first adhesive layer is formed over the backside of the dice. Next, a panel substrate having predetermined die through holes and a plurality of openings passing through the panel substrate is provided, wherein the die through hole is to receive the die. The panel substrate is bonded onto the backside of the dice. Then, an encapsulation material is filled into the die through holes and the plurality of openings. The laminate film is removed. Next, the panel substrate is bonded onto a carrier such that active region of the dice are upwardly, wherein the panel substrate includes conductive base and conductor and the conductive base may be forming a redistribution layer for electric connection. A second adhesive layer is formed over the protective layer. Finally, a laser marking process based on said second adhesive layer is utilized to form a marking layer.

The method further comprises a step of forming a conductive layer between the electronic element and the adhesive layer. The method further comprises a step of forming a conductive material on the panel substrate for signal connection. The method further comprises a step of forming signal channels over the electronic element and the connectors, and thereby connecting between the pads of said electronic element and the connectors. The method further comprises a step of forming a dielectric layer over the panel substrate, the encapsulation material and the dice to expose the conductors and the die pads. The method further comprises a step of forming a protective layer to cover the signal channels and the dielectric layer for protection. The method further comprises a step of sawing the panel substrate along the scribe line to singulate and separate the package into individual units.

### BRIEF DESCRIPTION OF THE DRAWINGS

FIG. 1 illustrates a cross-sectional view of a basic conductor package structure in accordance with one embodiment of the present invention.

FIG. 2 illustrates a cross-sectional view of a downward conductor package structure with signal channels in accordance with one embodiment of the present invention.

FIG. 3 illustrates a cross-sectional view of another downward conductor package structure with signal channels in accordance with one embodiment of the present invention.

FIG. 4 illustrates a cross-sectional view of a dual-side conductor package structure with signal channels in accordance with one embodiment of the present invention.

FIG. 5 illustrates a cross-sectional view of a stacking conductor package structure with signal channels in accordance with one embodiment of the present invention.

FIG. 6 illustrates a cross-sectional view of a twin-side stacking conductor package structure with signal channels in accordance with one embodiment of the present invention.

FIG. 7 illustrates a cross-sectional view of an upward stacking conductor package structure with wire bond in accordance with one embodiment of the present invention.

FIG. 8 illustrates a cross-sectional view of an individual conductor package structure in accordance with one embodiment of the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention are only for illustrating the present invention. Besides the preferred embodiment mentioned here, the present invention can be practiced in a wide range of other embodiments besides those explicitly described, and the scope of the present invention is expressly not limited except as specified in the accompanying claims.

The present invention discloses a conductor package structure utilizing a conductive base having predetermined die through holes and a plurality of openings passing through the conductive base. Signal channels are formed over an electronic element and via connectors, and thereby connecting between the electronic element and via connectors. A marking layer is formed over the signal channels.

FIG. 1 illustrates a cross-sectional view of a basic conductor package structure in accordance with one embodiment of the present invention. As shown in the FIG. 1, the conductor package structure includes a substrate having predetermined die through holes and a plurality of openings passing through the substrate, wherein the die through hole is to receive a die 102 with die pads 105 formed thereon. In one embodiment, the substrate includes a redistribution layer (RDL) 100 and conductors 104, wherein the redistribution layer 100 is formed between the conductors 104, and the bottom of the conductors 104 and the bottom of the redistribution layer 100 are coplanar. The material of the substrate includes alloy or metal. The alloy includes Alloy42 (42% Ni-58% Fe) or Kovar (29% Ni-17% Co-54% Fe). Preferably, the die 102 is an electronic element. The material of the redistribution layer 100 includes alloy or metal. Pluralities of the plurality of openings are created through the redistribution layer 100 from upper surface to lower surface of the redistribution layer 100. An adhesive layer (material) 101 is formed over the redistribution layer 100 for adhering the die 102. For example, the adhesive layer 101 comprises conductive material for electric conduction. Conductors 104 are formed between the surface of a filling material 103 passing through the filling material 103, wherein the conductors 104 comprise at least one material for signal connection (electrical communication). The filling material 103 is filled into the space (plurality of openings) between the electronic element 102 and the conductors 104. The filling material 103 is adjacent to the side wall of the electronic element 102 and the redistribution layer 100, and covers the active side of the electronic element 102. For example, the filling material 103 is surrounded by the redistribution layer 100, the electronic element 102 and the conductors 104. The redistribution layer 100 is coupled to the contactors 104. The electronic element 102 and the adhesive layer (material) 101 are encapsulated by the filling material 103.

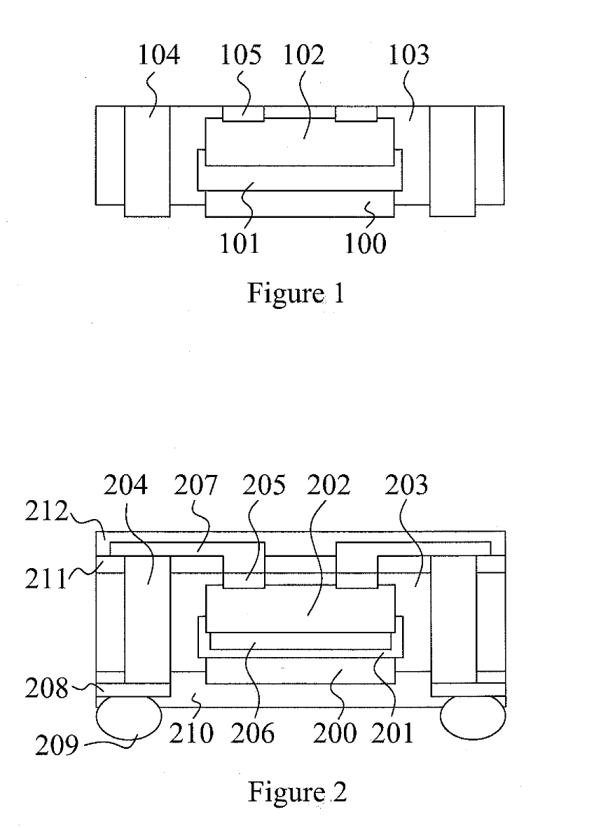

FIG. 2 illustrates a cross-sectional view of a downward conductor package structure with signal channels in accordance with one embodiment of the present invention. As shown in the FIG. 2, the downward conductor package structure includes a substrate comprised of conductive base 200 and conductors 204, wherein the conductive base 200 is formed between the conductors 204 and the bottom of the conductors 204 and the bottom of the conductive base 200 are coplanar. An adhesive layer (material) 201 is formed over the conductive base 200 for adhering a die 202. Preferably, the die 202 is an electronic element. For example, the adhesive layer 201 comprises conductive material. Conductors 204 are formed between the surface of a filling material 203 passing through the filling material 203, wherein the conductors 204 comprise at least one material for signal connection (electrical communication). The filling material 203 is filled into the space between the electronic element 202 and the conductors 204. The filling material 203 is adjacent to the side wall of the electronic element 202 and the conductive base 200, and covering the active side of the electronic element 202. For example, the filling material 203 is surrounded by the conductive base 200, electronic element 202 and the conductors 204. Contact pads (signal channels) 208 are located on the lower surface of the conductors 204 and connected to the conductors 204. A dielectric (buffer) layer 211 is formed over the electronic element 202 and the filling material 203, and under signal channels 207, to expose the conductors 204 and pads 205 of the electronic element 202. In one embodiment, the dielectric layer 211 comprises an elastic material, photosensitive material. Signal channels 207, for example redistribution layer (RDL), are formed over (upper surface of) the electronic element 202 and the connectors 204, and thereby connecting between the pads 205 of the electronic element 202 and via connectors 204. A conductive layer 206 is formed between the electronic element 202 and the adhesive layer 201 for electric conduction. A protective layer 210 is formed under the filling material 203 for protection and covers the filling material 203, the conductive base 200, the conductors 204 and the signal channels 208 to expose the signal channels 208. Solder bumps/balls 209 are formed under the signal channels 208 for signal connection. Another protective layer 212 is formed over (upper surface of) the signal channels 207 for protection and covers the dielectric (buffer) layer 211 and the signal channels 207. In one embodiment, material of the protective layers 210, 212 comprises SINR, silicone rubber, and the protective layer 210 may be formed by a molding or gluing method (dispensing or printing).

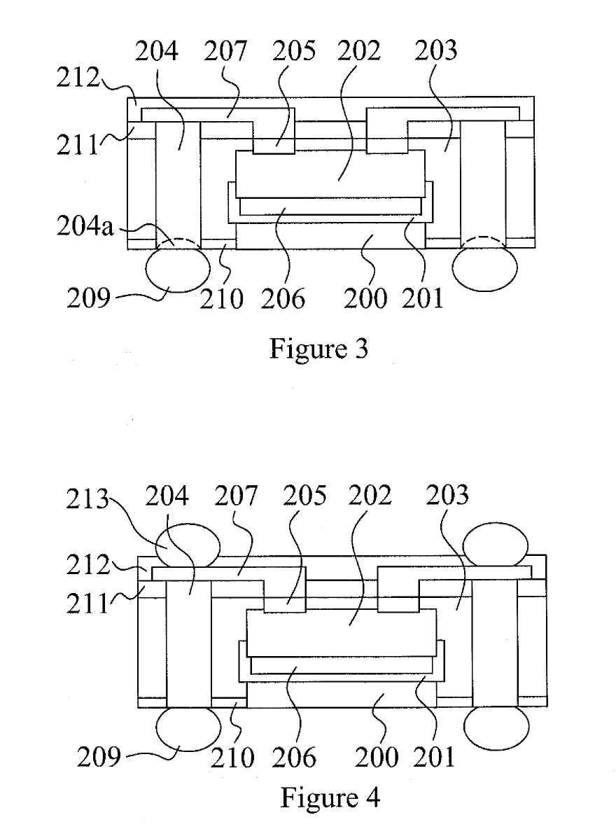

FIG. 3 illustrates a cross-sectional view of another downward conductor package structure with signal channels in accordance with one embodiment of the present invention. As shown in the FIG. 3, the downward conductor package structure omits signal channels 208. The protective layer 210 is formed under the filling material 203 for protection and covers the filling material 203 to expose the connectors 204 and the conductive base 200. Solder bumps/balls 209 are formed under the connectors 204 for signal connection. Most of the parts of the FIG. 3 are similar to FIG. 2; and therefore the detailed descriptions are omitted. In such embodiment, exposing conductive base 200 can enhance the performance of heat dissipation. In one embodiment, especially, the bottom of the conductors 204 has a concave shape portion 204a formed therein for facilitating aligning and receiving with the solder bumps/balls 209 such that the solder bumps/balls 209 may be accurately attached on the conductors 204. The concave shape portion 204a may be formed by a photolithography process and an etching process.

FIG. 4 illustrates a cross-sectional view of a dual-side downward conductor package structure with signal channels in accordance with one embodiment of the present invention. As shown in FIG. 4, the downward conductor package structure omits signal channels 208. The protective layer 210 is formed under the filling material 203 for protection and covers the filling material 203 to expose the connectors 204 and the conductive base 200. Solder bumps/balls 209 are formed under the connectors 204 for signal connection. The protective layer 212 is formed over (upper surface of) the signal channels 207 for protection and covers the dielectric (buffer) layer 211 and the signal channels 207 to expose the signal channels 207. Solder bumps/balls 213 are formed over the signal channels 207 for signal connection. Most of the parts of the FIG. 4 are similar to FIG. 2; and therefore the detailed descriptions are omitted. In such embodiment, exposing conductive base 200 can enhance the performance of heat dissipation.

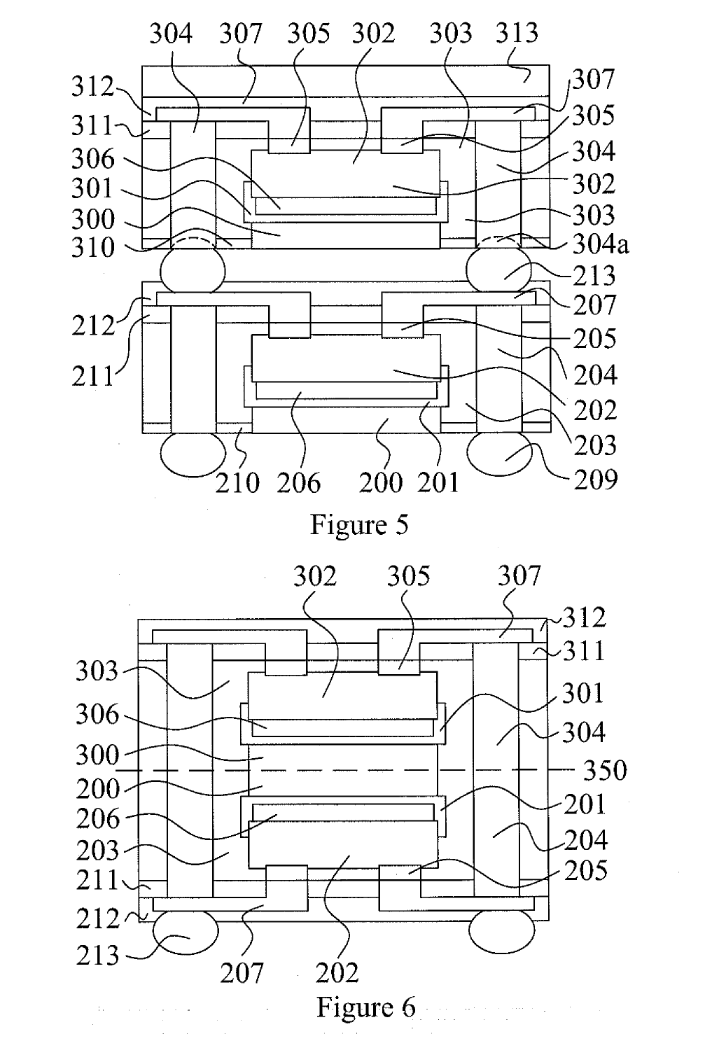

FIG. 5 illustrates a cross-sectional view of a stacking conductor package structure with signal channels in accordance with one embodiment of the present invention. As shown in the FIG. 5, it shows a stacking conductor package structure which can be made by an upper conductor package structure and a lower dual-side downward conductor package structure. Solder bumps/balls of the upper conductor package structure may be omitted. Solder bumps/balls 213 of the lower dual-side downward conductor package structure may be formed between the signal channels 207 and conductors 304 for signal connection. In such embodiment, parts of the upper conductor package structure are similar to FIG. 3, which includes a conductive base 300, an adhesive layer 301, an electronic element 302 with pads 305, a filling material 303, conductors 304, a conductive layer 306, signal channels 307, a protective layer 310, a dielectric layer 311, a protective layer 312 and a marking layer 313. The description of the parts of the upper conductor package structure may be referred to FIG. 2. The marking layer 313 is formed on the protective layers 312. In one embodiment, especially, the bottom of the conductors 304 has a concave shape portion 304a formed therein for facilitating aligning and receiving with the solder bumps/balls 213 such that the solder bumps/balls 213 may be accurately attached on the conductors 304. The concave shape portion 304a may be formed by a photolithography process and an etching process.

FIG. 6 illustrates a cross-sectional view of a twin side stacking conductor package structure with signal channels in accordance with one embodiment of the present invention. As shown in the FIG. 6, it shows a twin side stacking conductor package structure which can be made by an upper active area upward conductor package structure and a lower active area downward conductor package structure. The upper conductor package structure and lower conductor package structure may be an identical package structure, wherein the conductive base 200,300, the filling material 203,303 and the conductors 204,304 are configured with each other along a connection area 350. Solder bumps/balls of the upper conductor package structure may be omitted. Solder bumps/balls 213 of the twin side stacking conductor package structure may be connected to an external electrical component for signal connection. In such embodiment, parts of the upper and lower conductor package structure are similar to the FIG. 3, wherein the upper conductor package structure includes a conductive base 300, an adhesive layer 301, an electronic element 302 with pads 305, a filling material 303, conductors 304, a conductive layer 306, signal channels 307, a dielectric layer 311 and a protective layer 312, and wherein the lower conductor package structure includes a conductive base 200, an adhesive layer 201, an electronic element 202 with pads 205, a filling material 203, conductors 204, a conductive layer 206, signal channels 207, a dielectric layer 211, a protective layer 212 and solder bumps/balls 213. The detailed description of the parts of the upper and lower conductor package structure may be referred to FIG. 2.

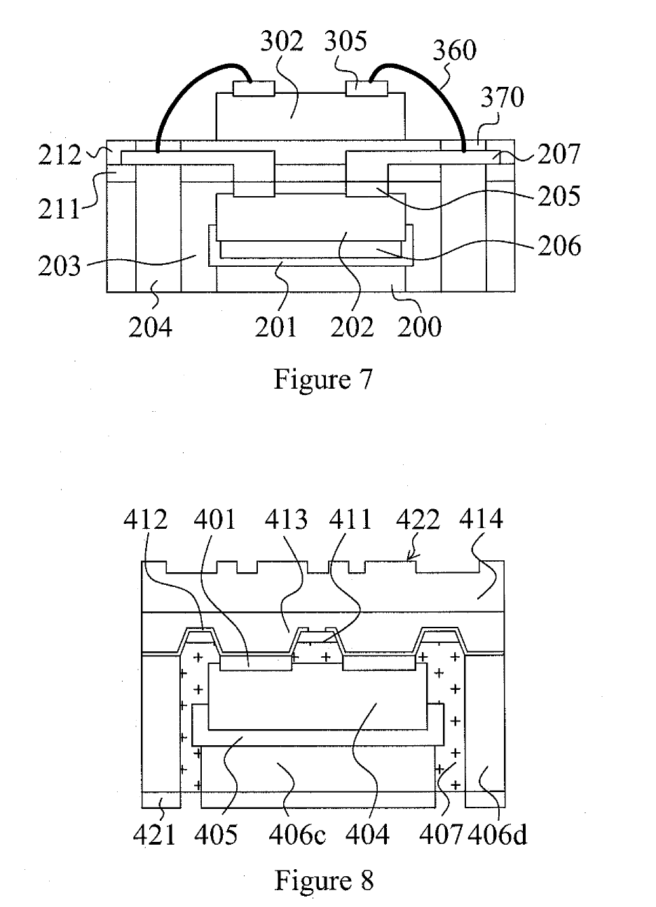

FIG. 7 illustrates a cross-sectional view of an upward stacking conductor package structure with signal channels in accordance with one embodiment of the present invention. As shown in FIG. 7, it shows an upward stacking conductor package structure which can be made by an electronic element 302 located on a lower conductor package structure, for example located on the protective layer 212. Die pad 305 of the electronic element 302 is electrically connected to the signal channels 207 of the lower conductor package structure through a wire bonding 360. One terminal of the wire bonding 360 is located on the exposed area 370 of the protective layer 212 to connect the signal channels 207, and the other terminal of the wire bonding 360 is located on the die pad 305 for electrical connection. In such embodiment, parts of the lower conductor package structure are similar to the FIG. 3, wherein the lower conductor package structure includes a conductive base, an adhesive layer 201, an electronic element 202 with pads 205, a filling material 203, conductors 204, a conductive layer 206, signal channels 207, a dielectric layer 211 and a protective layer 212. The detailed description of the parts of the lower conductor package structure may be referred to FIG. 2.

FIG. 8 illustrates a cross-sectional view of an individual conductor package structure in accordance with one embodiment of the present invention. An adhesive layer 405 is formed on a conductive base 406c. At least one electronic element 404 is formed on the adhesive layer 405. A plurality of conductors 406d formsignal connection between the surface of a filling material 407 and the bottom of said filling material, wherein the filling material 407 is filled in the space between the plurality of conductors 406d and around the electric element 404. The adhesive layer (conductive layer) 405 is located on the backside of a die 404 at a predetermined thickness. The conductive base 406c is formed between the conductors 406d, and the bottom of the conductors 406d and the bottom of the conductive base 406c are coplanar. A dielectric layer 411, for example SINR material, is formed over the conductors 406d, the encapsulation (filling) material 407 and the die 404 to expose the conductors 406d and the die pads 401. Signal channels 412, for example redistribution layer (trace), are formed over (upper surface of) the electronic element 404 and the connectors 406d, and thereby connecting between the pads 401 of the electronic element 404 and via connectors 406d. A protective layer 413 is formed to cover the signal channels 412 and the dielectric layer 411 for protection, and an adhesive layer 414 is formed over the protective layer 413. A conductive material 421 is configured on the lower surface of the conductive base 406c and the conductors 406d to solder joining an external object. The adhesive layer 414 is utilized by a laser marking process to form a marking surface 422.

It should be noted that the thickness of protective layer (film) is preferably around 0.1 um to 0.3 um and the reflection index close to the air reflection index 1. The materials of protective layer can be SiO₂, Al₂O₃ or Fluoro-polymer etc.

The communication traces penetrate through the substrate via the contact through holes, and therefore the thickness of the die package shrinks. The package of the present invention will be thinner than the prior art. Further, the substrate is pre-prepared before package. The die through hole and the contact through holes are pre-determined as well. Thus, the throughput will be improved.

Hence, the advantages of the present invention are:

The conductor substrate is pre-prepared with pre-form through hole; it can generate the super thin package due to die insert inside the substrate; it can be used as stress buffer releasing area by filling silicone rubber to absorb the thermal stress due to the CTE difference between silicon die (CTE˜2.3) and the conductor substrate. The packaging throughput will be increased (manufacturing cycle time was reduced) due to applying the simple process. The reliability for both package and board level is better than ever, so no thermal mechanical stress can be applied on the solder bumps/balls. The cost is low and the process is simple. The manufacturing process can be applied as fully automatic especially in module assembly. It is easy to form the combo package (dual dice package). It has high yield rate due to particles free, simple process, and full automation.

Although preferred embodiments of the present invention have been described, it will be understood by those skilled in the art that the present invention should not be limited to the described preferred embodiments. Rather, various changes and modifications can be made within the spirit and scope of the present invention, as defined by the following claims.

Having described the invention, the following is claimed:

1. A conductor package structure, comprising:
a redistribution layer;
an adhesive layer formed on said redistribution layer;
at least one electronic element formed on said adhesive layer; and
a plurality of conductors forming signal connection between the surface of a filling material and the bottom of said filling material, wherein said filling material is filled in the space between said plurality of conductors and around said electric element.

2. The structure of claim 1, wherein at least one opening is formed in said redistribution layer.

3. The structure of claim 1, wherein said redistribution layer is formed between said conductors, and the bottom of said conductors and the bottom of said redistribution layer are coplanar.

4. The structure of claim 1, wherein said adhesive layer comprises conductive material.

5. The structure of claim 1, wherein said filling material is adjacent to the side wall of said electronic element and said redistribution layer, and covers the active side of said electronic element.

6. The structure of claim 1, wherein said filling material exposes the top surface and the bottom surface of said conductors.

7. The structure of claim 1, further comprising a conductive layer formed between said electronic element and said adhesive layer.

8. The structure of claim 1, further comprising a conductive material formed under said conductors and said redistribution layer.

9. The structure of claim 1, further comprising signal channels formed over said electronic element and connecting between said electronic element and said connectors.

10. The structure of claim 9, further comprising a dielectric layer formed under said signal channels.

11. The structure of claim 10, further comprising a protective layer formed over said dielectric layer.

12. The structure of claim 11, further comprising a marking layer formed over said protective layer.

13. The structure of claim 11, wherein material of said protective layer includes silicone rubber.

14. The structure of claim 11, wherein said protective layer comprises elastic material, photosensitive material or dielectric material.

15. The structure of claim 11, further comprising a second electronic element formed on said protective layer formed over said dielectric layer.

16. The structure of claim 15, wherein a die of said second electronic element is connected to said signal channels through a wire bonding.

17. The structure of claim 1, wherein the material of said redistribution layer includes alloy or metal.

18. The structure of claim 1, wherein bottom of said conductors has a concave shape portion formed therein.
